(19) United States
(12) Patent Application Publication
(10) Pub. No.: US 2024/0257890 A1
(43) Pub. Date: Aug. 1, 2024

(54) METHODS AND APPARATUS TO SELECT ADDRESSES FOR MEMORY TRAINING

(71) Applicant: INTEL CORPORATION, Santa Clara, CA (US)

(72) Inventors: Zhiguo Wei, Shanghai (CN); Yanyang Tan, Sherwood, OR (US); John Vancleve Lovelace, Driftwood, TX (US)

(21) Appl. No.: 18/620,765

(22) Filed: Mar. 28, 2024

Related U.S. Application Data
(63) Continuation-in-part of application No. PCT/CN2024/080233, filed on Mar. 6, 2024.

(30) Foreign Application Priority Data
Mar. 6, 2024 (WO) PCT/CN2024/080233

(51) Int. Cl. G11C 29/12; G11C 29/30; G11C 29/44

(52) U.S. Cl. CPC G11C 29/1201; G11C 29/30; G11C 29/44

(57) ABSTRACT

Systems, apparatus, articles of manufacture, and methods are disclosed to select addresses for memory training. An example non-transitory computer readable medium comprising instructions that, when executed, cause a machine to determine a first memory address at which to perform memory input/output training based on an identification of a second memory address that is associated with an error, and cause the memory input/output training to be performed at the first memory address.

### RELATED APPLICATION

This patent arises from a continuation in part of International Application No. PCT/CN2024/080233, which was filed on Mar. 6, 2024. International Application No. PCT/CN2024/080233 is hereby incorporated herein by reference in its entirety. Priority to International Application No. PCT/CN2024/080233 is hereby claimed.

### FIELD OF THE DISCLOSURE

This disclosure relates generally to dynamic random access memory initialization and, more particularly, to method and apparatus to select addresses for memory training.

### BACKGROUND

Dynamic Random Access Memory (“DRAM”) is a specific type of volatile memory. When a device with a DRAM is powered on, the DRAM must be initialized before becoming operational. One process of the initialization procedure is read/write training. DRAM is commonly used as the main memory system in computers, servers, and other digital devices, where they provide temporary storage for data and instructions that are actively being processed by the central processing unit (CPU). DRAM is organized into rows and columns within memory banks, with each memory cell accessed by selecting a specific row and column address. An example type of DRAM is a double data rate (DDR) DRAM which uses double data rate transfer. DDR memory modules come in different generations such as DDR, DDR2, DDR4, and DDR5 each offering improvements in performance, efficiency, and capacity over its predecessors.

### BRIEF DESCRIPTION OF THE DRAWINGS

FIG. 1 is a block diagram of an environment in which a memory input/output (I/O) training circuitry operates to perform memory input/output training.

FIG. 2 is a block diagram of an example implementation of the memory input/output (I/O) training circuitry to perform memory input/output training.

FIG. 3 is a block diagram of example DDR5 memory sub-system.

FIG. 4 is a block diagram of example RDIMM DRAM device layout.

FIG. 5 is a block diagram of example DRAM storage organization hierarchy.

FIG. 6 illustrates example rows and columns in a DRAM bank.

FIG. 7 illustrates memory addresses used by Write DQ Delay Training.

FIG. 8 is a flowchart representative of example machine readable instructions and/or example operations that may be executed, instantiated, and/or performed by example programmable circuitry to implement the memory I/O training circuitry of FIG. 2.

FIG. 9 illustrates an example operation of the memory I/O training circuitry in an environment of use.

FIG. 10 is a block diagram of an example processing platform including programmable circuitry structured to execute, instantiate, and/or perform the example machine readable instructions and/or perform the example operations of FIG. 8 to implement the memory I/O training circuitry of FIG. 2.

FIG. 11 is a block diagram of an example implementation of the programmable circuitry of FIG. 10.

FIG. 12 is a block diagram of another example implementation of the programmable circuitry of FIG. 10.

FIG. 13 is a block diagram of an example software/firmware/instructions distribution platform (e.g., one or more servers) to distribute software, instructions, and/or firmware (e.g., corresponding to the example machine readable instructions of FIG. 8) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Initializing DRAM and other types of memory involves setting up the memory subsystem of a computer system to ensure that the memory modules are properly configured and ready for use. During the boot-up process of a computer system, the system firmware (e.g., BIOS) performs a series of tests including detecting and initializing essential hardware components, such as the memory modules. The system firmware detects the presence of the memory modules installed in the system. The system identifies the type, capacity, and configuration of each memory module including parameters such as speed, voltage, and timing settings. A memory controller performs memory training algorithms to optimize the timing parameters of the memory modules for reliable data transmission between the memory controller and the memory modules. This includes procedures such as data queue (DQ) delay training, which adjusts the timing of data signals to match the characteristics of the memory modules. The system firmware may perform memory testing to ensure the reliability and integrity of the memory modules. This may involve running memory test patterns or performing read/write training to verify data integrity.

The read/write training optimizes the timing parameters of the memory interface to maximize data transfer rates and reliability. This includes adjusting signal timing, delay settings, and voltage levels to match the characteristics of the memory modules and the memory controller. The memory controller evaluates the data capture margins for the read and write operations. The data capture margins represent the difference between the signal timing and the sampling window, indicating the reliability of data transmission. A zero margin error occurs when the data capture margin is insufficient, indicating potential timing violations and the risk of data errors. When a zero margin error is reported, the memory controller may take corrective actions such as disabling specific memory channels.

For RDIMM, a write DQ delay training is the first training operation which accesses the DRAM rows. Examples disclosed herein aim to improve the memory DQ read/write training to avoid disabling memory channels when a zero margin error is reported but instead attempt to retry the DQ training process with different settings by modifying the read/write training operations. Typically, during the write DQ delay training, if zero margin is reported for any DQ lane, basic input output system (BIOS) memory reference code (MRC) attributes the zero margin error to a write data path failure. The MRC reports a fatal write data path error and disable the whole memory channel. Current MRC does not check whether the zero margin error is caused by a DRAM row failure. Over time, more memory rows would age and fail. During cold reboot which requires write DQ delay training, if MRC uses these failing memory rows during training, the training code will report a zero margin error, which is a fatal error and would lead to a system hang. For a single row failure in a DRAM, the probability of training failure caused by it would be 320 defect per million (DPM). The examples disclosed herein aim to improve DRAM write DQ delay training. If the zero margin error is caused by DRAM row failure, the zero margin error is recoverable. The DRAM row failure can be repaired using post package repair (PPR) procedure to replace failing rows with backup rows. The example disclosed herein records failing memory addresses during write DQ delay training. Subsequent write DQ delay training avoids those failing addresses, and retry training on different addresses. Then the write DQ delay training identifies a DRAM row failure, MRC applies PPR on those failing rows to recover the failing DRAM.

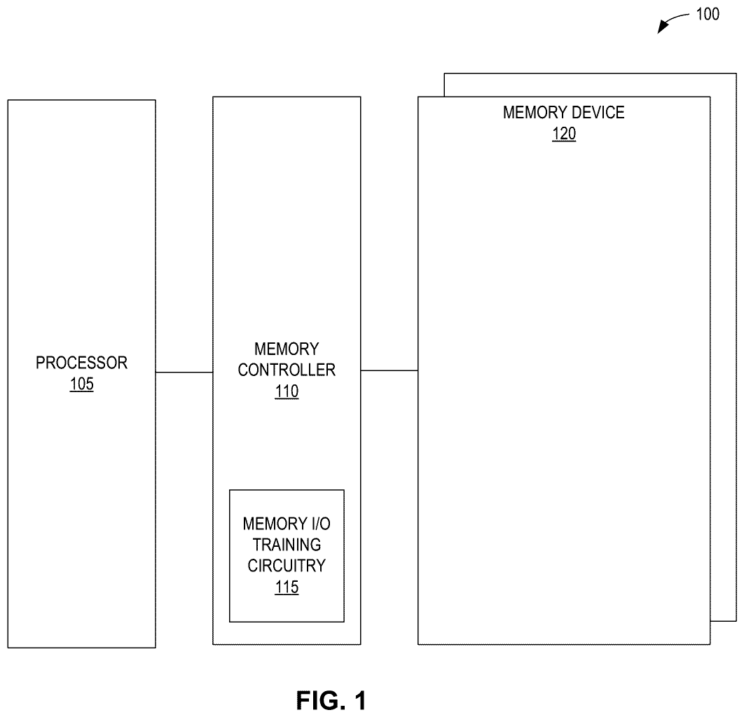

FIG. 1 is a block diagram of an example environment 100 in which a memory input/output (I/O) training circuitry operates to perform memory input/output training. The example environment 100 includes a processor 105, a memory controller 110 including the memory input/output (I/O) training circuitry 115 and memory devices 120.

The processor 105 initiates and manages operations in the memory devices. The processor 105 initializes a DQ delay training process by sending specific commands to the memory controller 110 to read from or write to the memory devices 120.

The memory controller 110 controls the flow of data between the processor 105 and the memory device 120. It interprets the commands from the processor 105 and coordinates the memory operations accordingly. The memory controller 110 communicates directly with the memory device 120 to perform tasks such as activating rows, selecting columns, and reading or writing data. In DQ delay training, the memory controller 110 generates training patterns and sends them to the memory device 120. These patterns are used to evaluate the timing of the DQ signals relative to the clock signal. The memory controller 110 captures and evaluates the received data to assess the effectiveness of the DQ delay adjustment performed by the memory devices 120. The DQ delay adjustment process continues iteratively until the optimal delay settings are determined, ensuring that the DQ signals are properly aligned with the clock signal. Once the DQ delay training process is complete, the memory controller 110 may perform additional verification process to ensure the reliability and stability of the DQ signal timing adjustments.

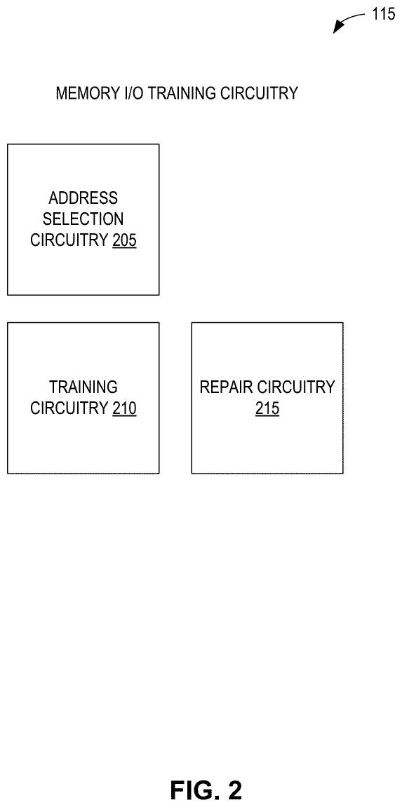

The memory I/O training circuitry 115 manages row failures in the DQ delay training. The memory I/O training circuitry 115 will be discussed below in connection with FIG. 2.

The memory device 120, typically a DRAM, stores data and is accessed by the memory controller 110. During the DQ delay training, the memory devices 120 adjust the timing (e.g., delay) of its DQ signals relative to a clock signal under the guidance of the memory controller 110. The memory devices 120 adjusts the delay of its DQ signals based on the received training patterns.

FIG. 2 is a block diagram of an example implementation of the memory input/output (I/O) training circuitry 115 of FIG. 1 to perform the write DQ delay training on DDR5. The memory I/O training circuitry 115 of FIG. 2 may be instantiated (e.g., creating an instance of, bring into being for any length of time, materialize, implement, etc.) by programmable circuitry such as a Central Processor Unit (CPU) executing first instructions. Additionally or alternatively, the memory I/O training circuitry 115 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

The example memory I/O training circuitry 115 includes example address selection circuitry 205, example training circuitry 210, and example repair circuitry 215.

The example address selection circuitry 205 determines a first memory address at which to perform a memory input/output training based on an identification of a second memory address that is associated with an error. The memory address identifies a row address of a DRAM. The first memory address identifies a row that does not include any memory addresses associated with an error. The address selection circuitry 205 identifies a row that does not include any memory addresses associated with an error across multiple memory modules. The second memory address is identified in a list of memory addresses associated with errors. The list of failing memory addresses associated with error is address that have been detected by MRC write DQ delay training, BIOS MRC advanced memory test or reliability, availability, and stability (RAS) runtime code and recorded in a non-volatile memory. The data structure recording the list of memory addresses associated with error is a post package repair (PPR) list. In a next reboot which requires write DQ delay training, the write DQ delay training checks the PPR repair list to avoid these failing addresses.

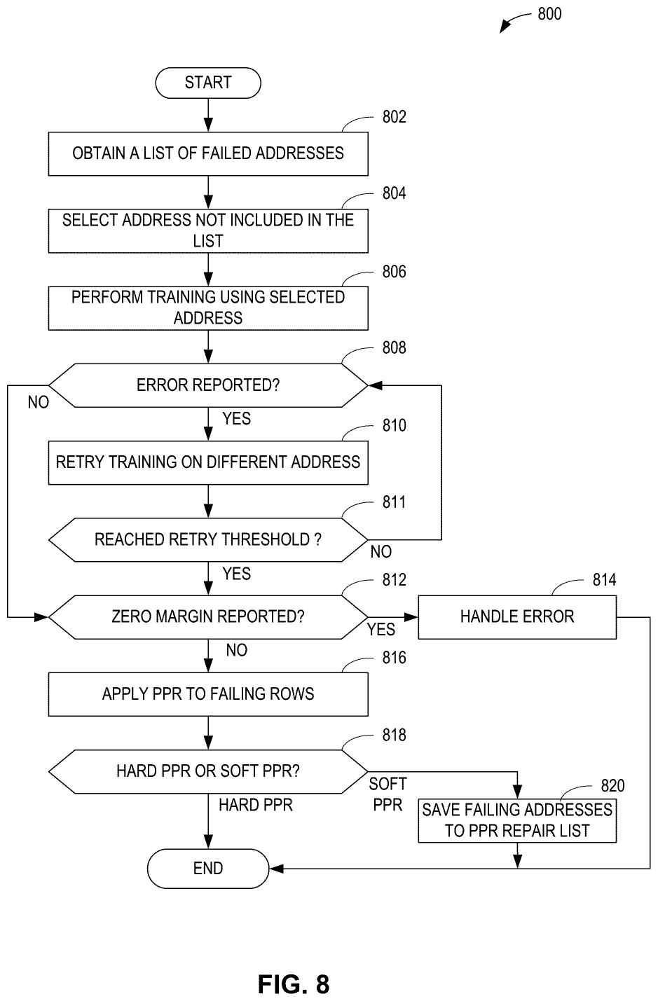

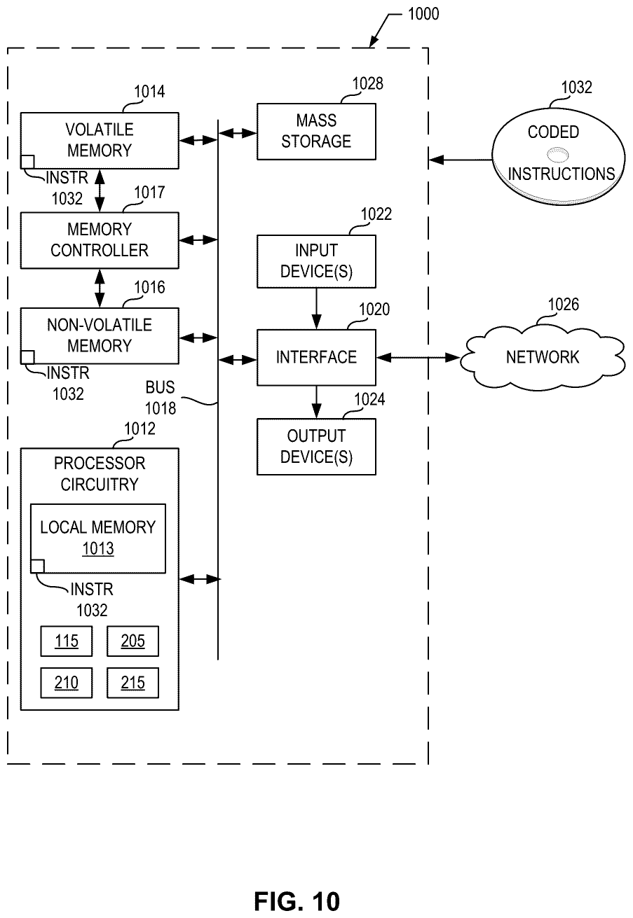

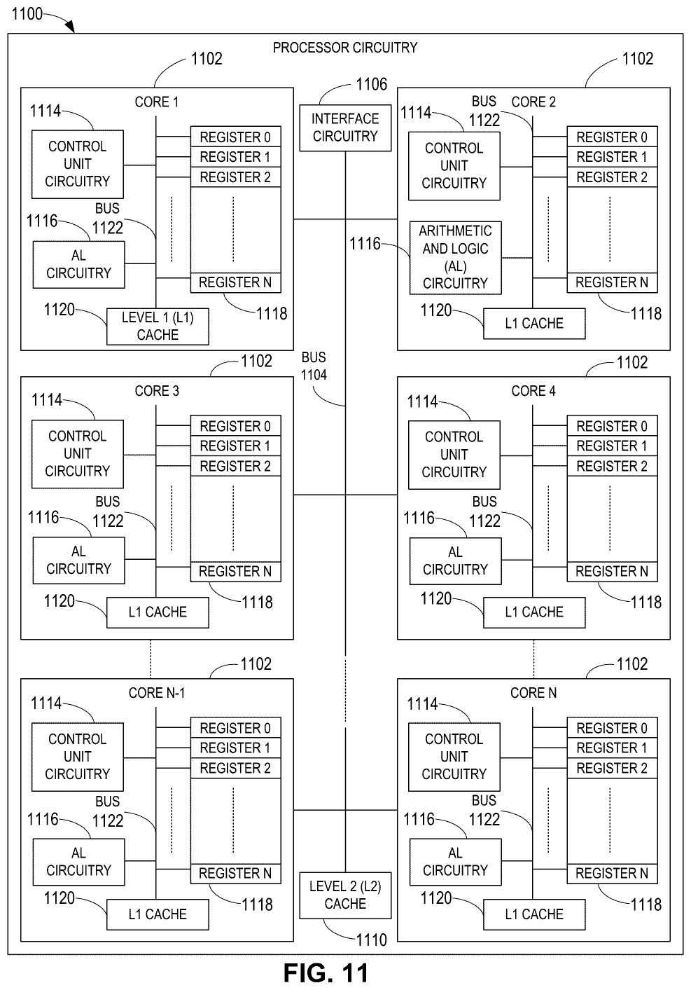

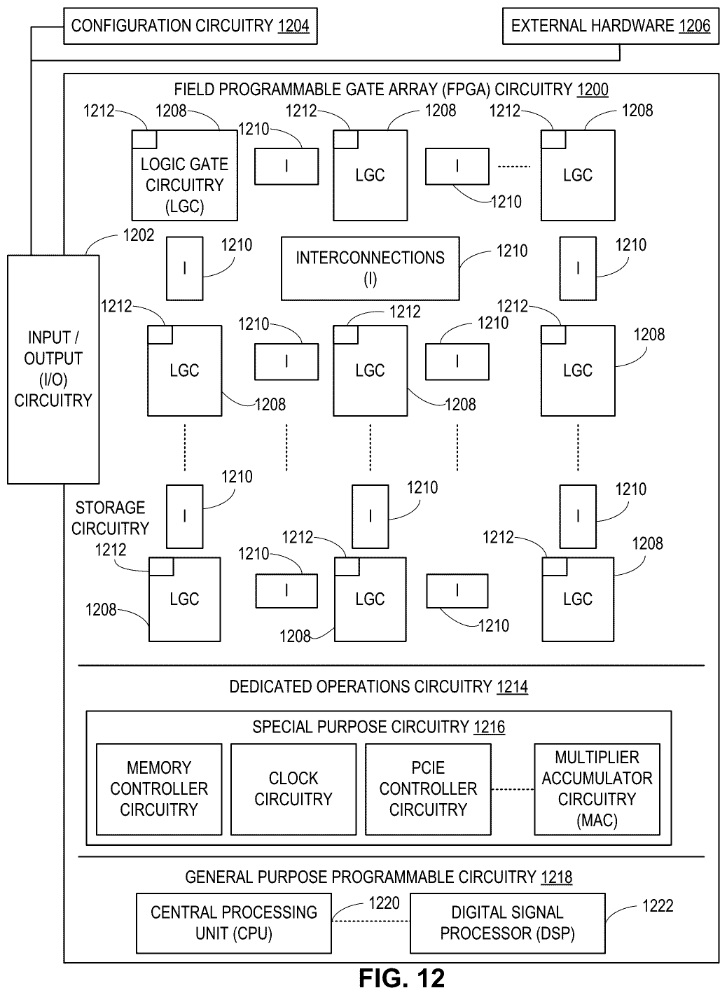

In some examples, the memory I/O training circuitry includes means for determining a first memory address at which to perform memory input/output training. For example, the means for determining may be implemented by an address selection circuitry 205. In some examples, the address selection circuitry 205 may be instantiated by programmable circuitry such as the example programmable circuitry 1012 of FIG. 10. For instance, the address selection circuitry 205 may be instantiated by the example microprocessor 1100 of FIG. 11 executing machine executable instructions such as those implemented by at least blocks 802, 804 of FIG. 8. In some examples, the address selection circuitry 205 may be instantiated by hardware logic circuitry, which may be implemented by an ASIC, XPU, or the FPGA circuitry 1200 of FIG. 12 configured and/or structured to perform operations corresponding to the machine readable instructions. Additionally or alternatively, the address selection circuitry 205 may be instantiated by any other combination of hardware, software, and/or firmware. For example, the address selection circuitry 205 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example training circuitry 210 performs memory input/output training on a selected memory address. If a memory input/output training fails or detects a zero margin error, the training circuitry 210 performs the memory input/output training on another memory address. The training circuitry 210 determines if the result of the memory input/output training is an error, and retry the memory input/output training using a second memory address. The memory training includes performing read/write training test on the first memory addresses. The read/write training test is performed on a second memory address in response to a failed test using the first memory address.

In some examples, the memory I/O training circuitry includes means for performing memory input/output training. For example, the means for performing memory input/output training may be implemented by the training circuitry 210. In some examples, training circuitry 210 may be instantiated by programmable circuitry such as the example programmable circuitry 1012 of FIG. 10. For instance, the training circuitry 210 may be instantiated by the example microprocessor 1100 of FIG. 11 executing machine executable instructions such as those implemented by at least blocks 806, 808, 810, 811, 812 of FIG. 8. In some examples, the training circuitry 210 may be instantiated by hardware logic circuitry, which may be implemented by an ASIC, XPU, or the FPGA circuitry 1200 of FIG. 12 configured and/or structured to perform operations corresponding to the machine readable instructions. Additionally or alternatively, the training circuitry 210 may be instantiated by any other combination of hardware, software, and/or firmware. For example, the training circuitry 210 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example repair circuitry 215 repairs a memory address after an error is determined after a memory input/output training. A first memory address is repaired when a read/write training test caused a failure on the first memory address. During a write DQ delay training, failing addressed will be stored in a PPR repair list. Once write DQ delay training has passed, MRC applies PPR on those failing addresses to recover the failing DRAM. PPR is a DRAM row sparing feature which replaces failing rows with back up rows (also known as PPR resource). PPR is intended to improve memory reliability and availability.

In some examples, the memory I/O training circuitry 115 includes means for repairing memory addresses. For example, the means for repairing may be implemented by the repair circuitry 215. In some examples, the repair circuitry 215 may be instantiated by programmable circuitry such as the example programmable circuitry 1012 of FIG. 10. For instance, the repair circuitry 215 may be instantiated by the example microprocessor 1100 of FIG. 11 executing machine executable instructions such as those implemented by at least blocks 816, 818, 820 of FIG. 8. In some examples, the repair circuitry 215 may be instantiated by hardware logic circuitry, which may be implemented by an ASIC, XPU, or the FPGA circuitry 1200 of FIG. 12 configured and/or structured to perform operations corresponding to the machine readable instructions. Additionally or alternatively, the repair circuitry 215 may be instantiated by any other combination of hardware, software, and/or firmware. For example, the repair circuitry 215 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the memory I/O training circuitry of FIG. 1 is illustrated in FIG. 2, one or more of the elements, processes, and/or devices illustrated in FIG. 2 may be combined, divided, re-arranged, omitted, eliminated, and/or implemented in any other way. Further, the example address selection circuitry 205, the example training circuitry 210, the example repair circuitry, and/or, more generally, the example memory I/O training circuitry 115 of FIG. 2, may be implemented by hardware alone or by hardware in combination with software and/or firmware. Thus, for example, any of the example address selection circuitry 205, the example training circuitry 210, the example repair circuitry 215, and/or, more generally, the example memory I/O training circuitry 115, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example memory I/O training circuitry 115 of FIG. 2 may include one or more elements, processes, and/or devices in addition to, or instead of, those illustrated in FIG. 2, and/or may include more than one of any or all of the illustrated elements, processes and devices.

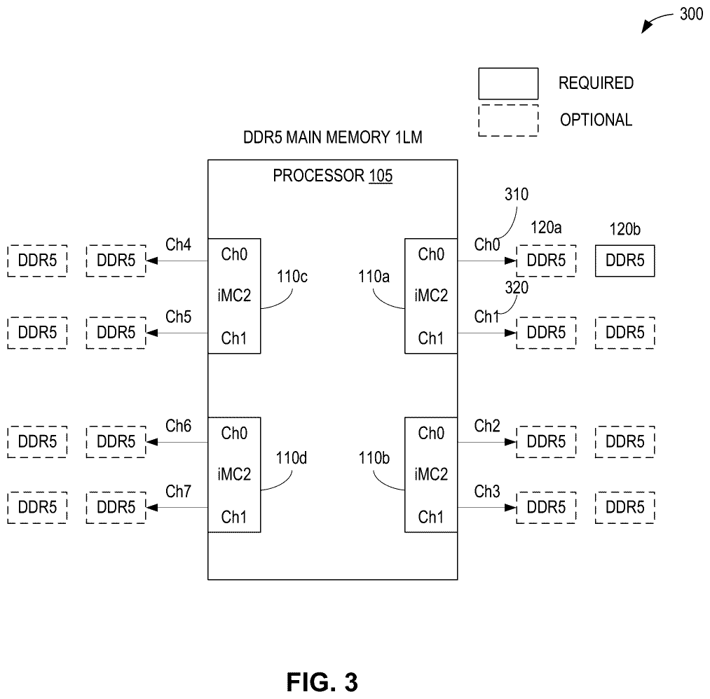

FIG. 3 is a block diagram of example double data rate 5 (DDR5) memory sub-system used to control and access external memory devices. In the illustrated example of FIG. 3, the DDR5 memory sub-system 300 includes an example processor 105 including four example DDR5 integrated memory controllers (iMC) 110A, 110B, 110C, 110D, two example DDR5 channels per iMC 310, 320, and example external dual in-line memory modules (DIMMs) 120A, 120B. The two DDR5 channels 310, 320 are shown as channel 0 and channel 1 in FIG. 3. There are two DDR5 DIMMs 120A, 120B populated on each channel. These components are interconnected through internal and external buses. The memory physical address is designed as a hierarchy of <Memory controller, Channel, Sub channel, DIMM, Rank, DRAM, Bank Group, Bank, Row, Column>.

A central processing unit (CPU) 105 can have multiple memory controllers integrated, which are in charge of translating CPU memory access request or training engine memory access request to JEDEC (Joint Electron Device Engineering Council) compatible commands and addresses to access external memory. The memory controller 110A is connected to DDR5 Physical Layer, which is responsible for delivering logical signal from memory controller 110A to analog signal for external DIMM 120A, 120B access, or vice versa. The memory controller 110A and DDR5 Physical Layer consist of multiple independent channels and sub channels for simultaneous data transfer. Each sub channel (e.g., channel 0 and channel 1) will extend the connection to external DIMM 120A, 120B through DDR5 bus.

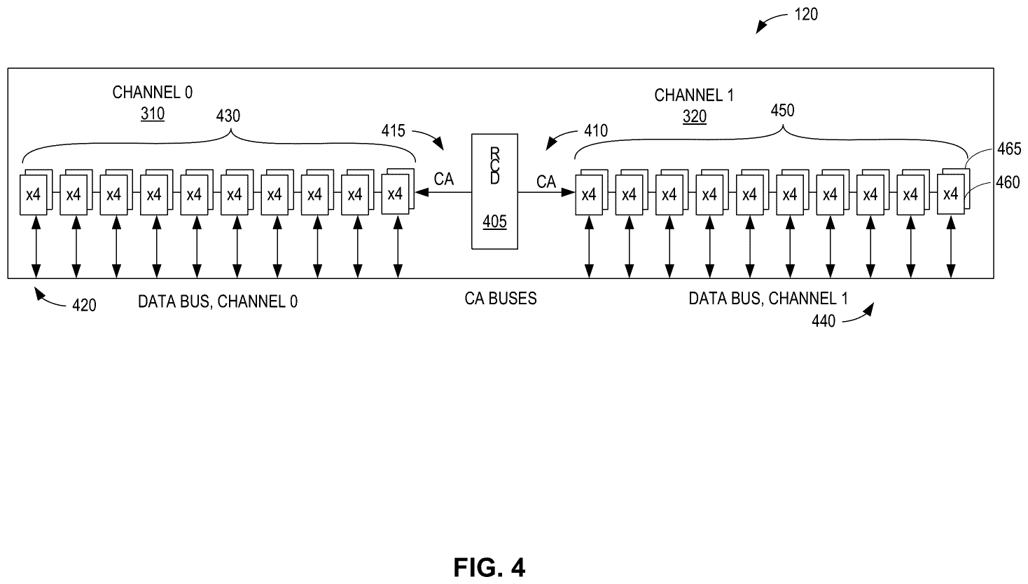

FIG. 4 is a block diagram of example layout of the RDIMM DRAM device 120. The RDIMM DRAM device 120 includes two sub-channel 310, 320 (e.g., channel 0 and channel 1), row to column delay 405, command/address buses 410, 415, data buses 420, 440 for channel 0 and channel 1, respectively. Within each sub channel 310, 320 (e.g., channel 0 or channel 1), there are two maximal registered DIMM (RDIMM) and two maximal DDR5 ranks 460, 465 for each RDIMM. Only one RDIMM is shown per channel in FIG. 4. A rank is a combination of DRAM devices. Each rank includes a set of memory chips that are accessed together as a unit.

In the illustrated example of FIG. 4, each rank 460 or 465 in the x4 RDIMM 120 includes ten x4 DRAM devices (e.g., 430 or 450), which could drive x32 data width and x8 error-correcting code (ECC) of a sub channel.

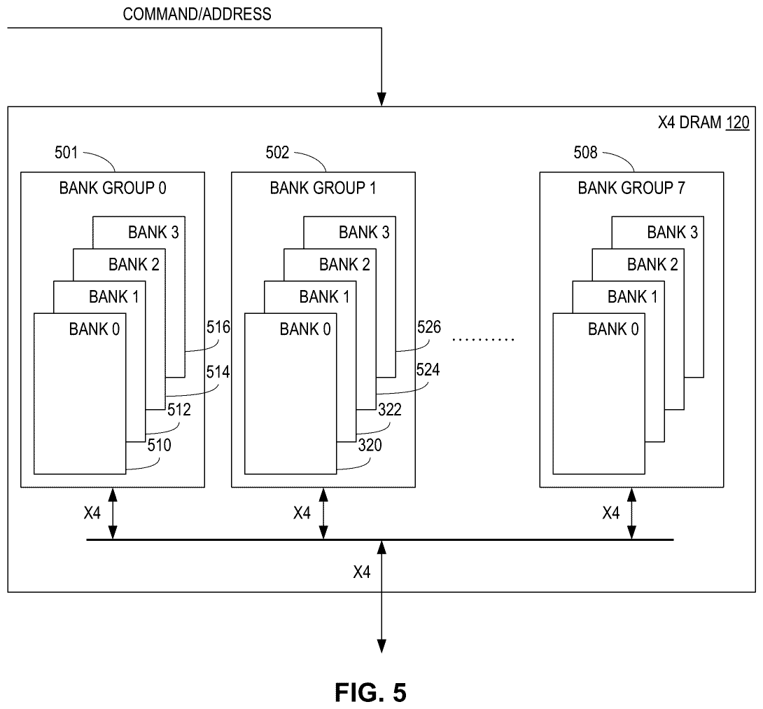

FIG. 5 is a block diagram of example DRAM storage organization hierarchy 500. The DRAM device storage is organized in a hierarchy of bank groups and banks. Each DRAM 120 includes several bank groups, and each bank group includes several banks. Banks are organized into bank groups to support interleaved access, which improves parallelism inside DRAM 120 to increase I/O bandwidth.

In the illustrated example of FIG. 5, the x4 DRAM 120 includes eight bank groups (e.g., bank group 0, bank group 1, bank group 2, bank group 3, bank group 4, bank group 5, bank group 6, bank group 7) and four banks (e.g., bank 0, bank 1, bank 2, bank 3) in each bank group.

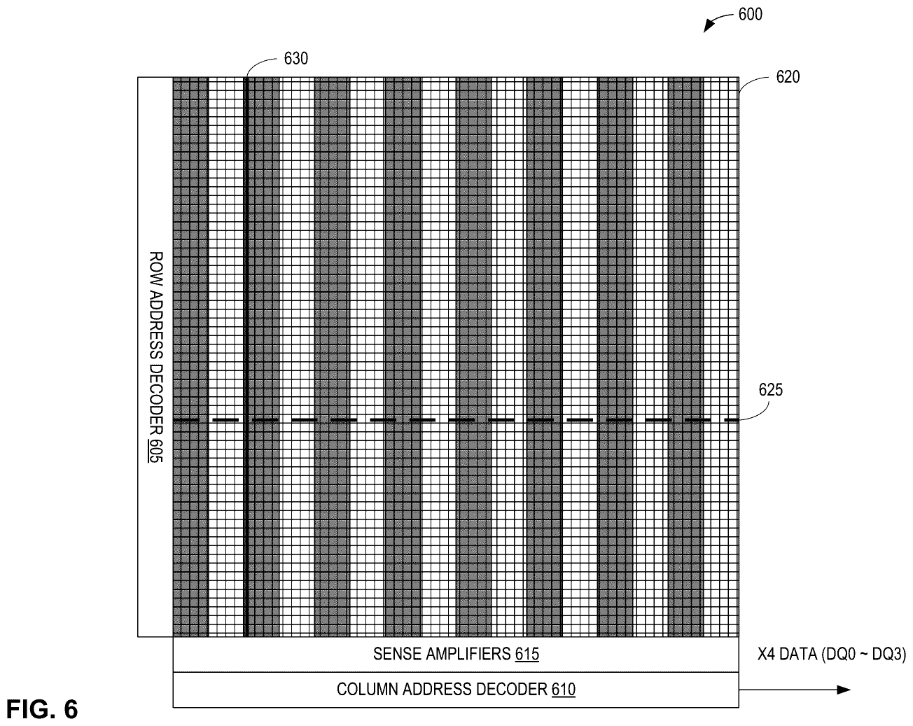

FIG. 6 illustrates example rows and columns in a DRAM bank 600, including a row address decoder 605, a column address decoder 610, sense amplifiers 615, and charge storage cells 620. A DRAM bank 600 is usually arranged in a rectangular array of charge storage cells 620. The long horizontal lines 625 are called rows and are accessed simultaneously. Each vertical line 630 is known as a bit-column. The bit-column 630 connects one DRAM cell 620 from each row to a sense amplifier 615. The DRAM cell 620 stores data as charge in a capacitor. The sense amplifier 615 reads or manipulates a DRAM cell's value by sampling or driving a bit-column. For a DDR5 X4 DRAM, four bit-columns form one X4 column. During DDR5 read/write operation to a X4 DRAM, a 4-bit data from the <Row, X4 Column> address is read/written during one clock unit interval (UI), and 16 consecutive X4 columns from a row are burst by one read/write, which forms 8-byte data.

In the illustrated example of FIG. 6, the row address decoder 605 is used for selecting a specific row within a DRAM bank 600 based on the row address provided by the memory controller 110 (FIG. 1). When the memory controller 110 sends a memory access request, it includes both the row and column address. The row address decoder 605 decodes the row address and activates the corresponding row in the DRAM bank 600. Once the row is activated, the data stored in that row becomes available for read or write operations.

The column address decoder 610 is used for selecting a specific column within the activated row to access the desired data. After the row is activated, the memory controller 110 sends the column address to the DRAM 600. The column address decoder 610 decodes the column address and selects the appropriate column within the activated row. Once the column is selected, the data in that column can be read from or written to.

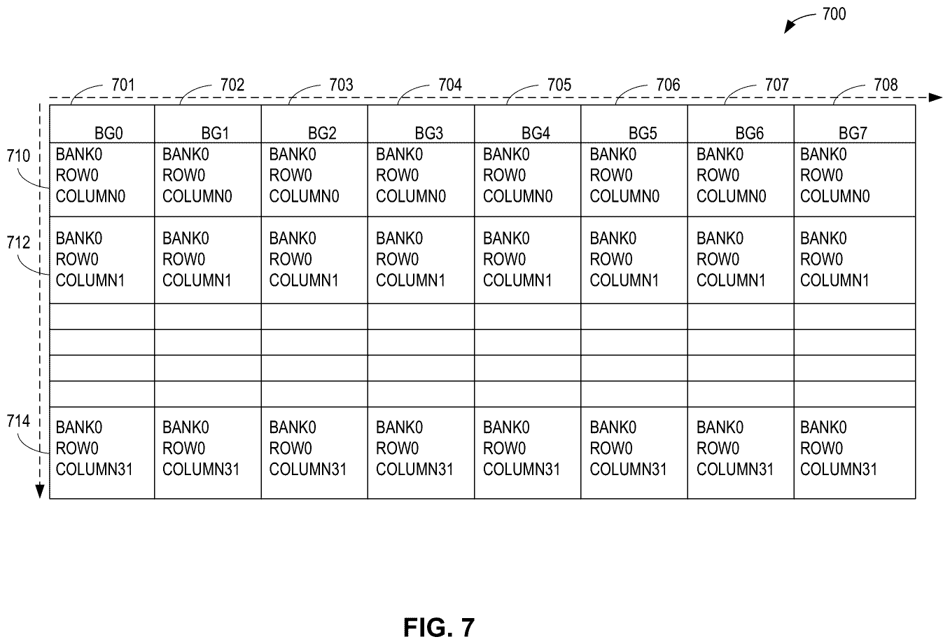

FIG. 7 illustrates memory addresses 700 used by memory test during DDR5 write data queue (DQ) delay training. The DDR5 write DQ delay training is done rank by rank. Each rank includes eight bank groups (501-508), four banks per bank group, 16 rows per bank and 32 columns per bank. In each bank group, a BIOS MRC selects memory cells located in Bank 0 and Row 0 of the memory module to test. The BIOS may proceed to test other memory cells by incrementing the address by bank group, and column, while maintaining the bank and row number at 0. For example, address 710 test bank 0, row 0 and column 0, address 712 test bank 0, row 0, and column 1, and address 714 test bank 0, row 0 and column 31.

During write DQ delay training, if any memory address in the address pattern fails, the data will be damaged, and the memory test will report a test failure for all write DQ DQS delay timing values. The BIOS MRC training algorithm will report zero margin for write DQ delay training. If a 4 Gb x4 DRAM fails in one row, the probability that the failing row falls into the address pattern of FIG. 7 is ½¹⁸. If the DIMMS are x4 DIMMS and maximal 4 ranks per channel, the failing probability per channel will be 20*4*(½¹⁸), which is 320 defect per million (DPM).

Flowchart(s) representative of example machine readable instructions, which may be executed by programmable circuitry to implement and/or instantiate the memory I/O training circuitry 115 of FIG. 2 and/or representative of example operations which may be performed by programmable circuitry to implement and/or instantiate the memory I/O training circuitry 115 of FIG. 2, are shown in FIG. 8. The machine readable instructions may be one or more executable programs or portion(s) of one or more executable programs for execution by programmable circuitry such as the programmable circuitry 1012 shown in the example processor platform 1000 discussed below in connection with FIG. 10 and/or may be one or more function(s) or portion(s) of functions to be performed by the example programmable circuitry (e.g., an FPGA) discussed below in connection with FIGS. 11 and/or 12. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 8, many other methods of implementing the example memory I/O training circuitry 115 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 8 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 8 is a flowchart representative of example machine readable instructions and/or example operations 800 that may be executed, instantiated, and/or performed by programmable circuitry to perform memory input/output training. The example machine-readable instructions and/or the example operations 800 of FIG. 8 begin at block 802, at which the example address selection circuitry 205 obtain a list of failed addresses. The address selection circuitry 205 selects address not included in the list (block 804).

The example training circuitry 210 performs training on the DRAM using selected addresses (block 806). The training can be a write DQ delay training of DRAM or any other memory training. The training circuitry 210 detects if an error is reported from the training (block 808). If an error is not reported (block 808: NO), instructions and/or operations 800 of FIG. 8 end. If a training error is reported (block 808: YES), the training circuitry 210 retry training on different addresses (block 810). In some examples, the retry training can be performed on different row addresses. The training circuitry 210 continue to try different row addresses until a retry threshold is reached. If the training circuitry 210 has not reached a retry threshold (block 811: NO), control returns to block 808 to determine if an error was detected on the retry training on the new row address. If a retry threshold is reached (block 811: YES), the training circuitry 210 conclude that the training errors are not due to internal DRAM row faults, but rather interconnect or input output (IO) faults resulting in zero margin error. The training circuitry 210 determines whether a zero margin error is reported (block 812). If a zero margin error is reported (block 812: YES), the memory controller 110 (FIG. 1) handles the error (block 814) by adjusting the write DQ delay settings, fine-tuning the delay settings for the DQ lines to optimize the timing of write operations. The memory controller 110 can increase or decrease the delay values to find the optimal settings that provides a sufficient margin for data capture. The instructions and/or operations 800 of FIG. 8 end.

If a zero margin error is not reported (block 812: NO), an example repair circuitry 215 apply post package repair (PPR) to failing rows (block 816). The repair circuitry 215 determines if a hard PPR or soft PPR is required (block 818: HARD). If a hard PPR is required (block 818: YES), the repair circuitry 215 replaces the failing row with a back-up row. The instructions and/or operations 800 of FIG. 8 end. If a soft PPR is required (block 818: SOFT), the repair circuitry 215 save the failing addresses to a PPR repair list (block 820). The instructions and/or operations 800 of FIG. 8 end.

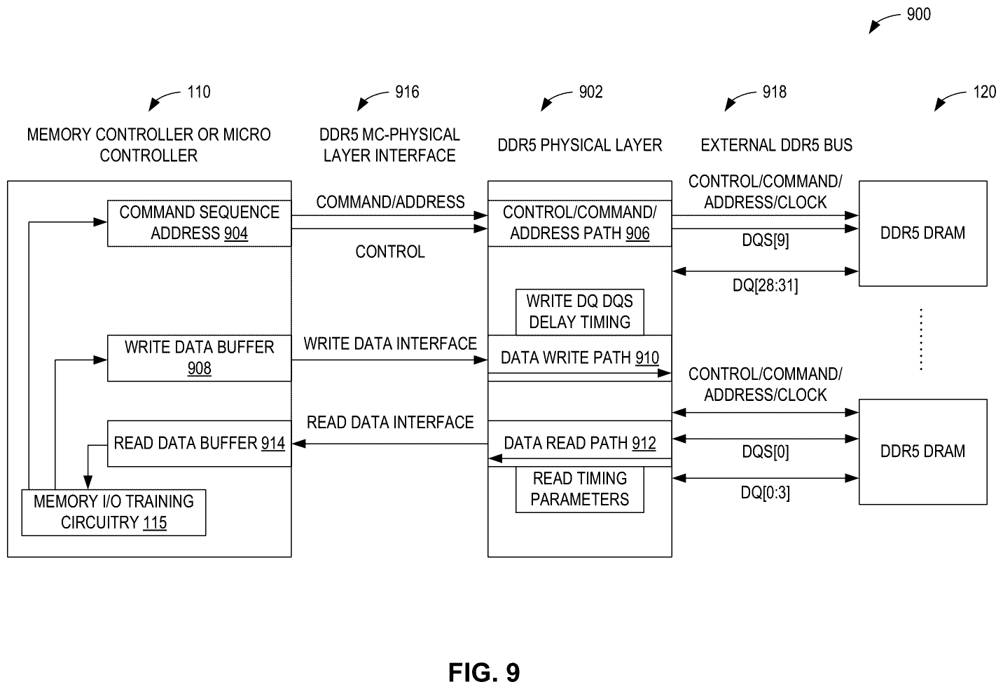

FIG. 9 illustrates an example operation 900 of the memory I/O training circuitry in an environment of use. The example operation 900 includes an example memory controller 110 including an example memory I/O training circuitry 115, example DDR5 DRAM 120, and example DDR5 physical layer 902. For example, the memory controller 110 can correspond to any of the memory controller 110A, 110B, 110C, 110D above. The DDR5 DRAM 120 can correspond to any of the DDR5 DRAM 120A, 120B, 430, 450 above. In a write DQ delay training, the memory test algorithm tests the memory sub-system data transfer, to see if the data write path can successfully transfer data at a particular timing value.

In the illustrated example operation 900, the memory controller 110 manages communication between the processor 105 (FIG. 1) and the memory modules 120. The memory controller 110 handles tasks such as issuing commands, controlling the timing of data transfers, and managing data flow between the processor 105 and memory module 120. The memory controller is in charge of translating CPU memory access request or training engine memory access request to JEDEC (Joint Electron Device Engineering Council) compatible commands and addresses to access external memory 120 (e.g., DRAM).

The example memory I/O training circuitry 115 creates specific sequence of commands to be sent to the DDR5 memory modules 120. These commands include read, write, activate, pre-charge, and others, which are necessary for accessing and modifying data stored in memory cells. Before write DQ delay training, all command, control, read signals, and write DQS signals have been trained to work properly. The BIOS MRC configures the memory I/O training circuitry 115 to generate a particular write and read command sequence to write pre-defined data pattern into DRAM, and then read them back. The memory I/O training circuitry 115 generates a sequence of write commands targeting selected memory address on DIMM, along with a particular data pattern. The memory I/O training circuitry 115 sends the command sequence address 904 to the DRAM 120 through the control/command/address path 906 in the DDR5 physical layer 902. The data in the write data buffer 908 is delivered to DRAM through an example data write path 910 to the DRAM 120. After the data pattern has been written into DRAM 120, the memory I/O training circuitry 115 generates a sequence of read commands to read back the data that it has been written. The data from the DRAM 120 will be read back through the data read path 912 and stored in the read data buffer 914. The memory I/O training circuitry 115 compares the read back data with the pre-defined data pattern to check if there is any error during the data transfer. If there is a data error, the BIOS MRC will mark the current write DQ delay training value as a failing timing value. The current BIOS MRC algorithm assumes that the DRAM storage cells are healthy and that all data errors are attributed to the write DQ delay timing of DDR5 physical layer. But in fact, if any of the DRAM storage cells that were used by the memory test are faulty, the data will also be damaged, and the memory test will also report a test failure for all write DQ delay timing values. The BIOS MRC training algorithm will report zero margin for the write DQ delay training.

In the illustrated example of FIG. 9, the memory I/O training circuitry 115 transmits the command and address instructions to the control/command/address path 908 via an example DDR5 memory controller (MC)-physical layer interface 916. The DDR5 physical layer 902 converts the logical signal to analog signal to be sent to the DDR5 DRAM 120. The DDR5 physical layer 902 communicates with the DRAM 120 via example external DDR5 bus 918.

The DDR5 write DQ delay training is done rank by rank. To achieve maximal input/output performance, BIOS MRC will configure the memory I/O training circuitry 115 to access DRAM banks in an interleaved manner, which means that the neighboring write/read commands are written to different bank groups.

FIG. 10 is a block diagram of an example programmable circuitry platform 1000 structured to execute and/or instantiate the example machine-readable instructions and/or the example operations of FIG. 8 to implement the memory I/O training circuitry 115 of FIG. 2. The programmable circuitry platform 1000 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1000 of the illustrated example includes programmable circuitry 1012. The programmable circuitry 1012 of the illustrated example is hardware. For example, the programmable circuitry 1012 can be implemented by one or more integrated circuits, logic circuits, FPGAs, microprocessors, CPUs, GPUs, DSPs, and/or microcontrollers from any desired family or manufacturer. The programmable circuitry 1012 may be implemented by one or more semiconductor based (e.g., silicon based) devices. In this example, the programmable circuitry 1012 implements address selection circuitry 205, training circuitry 210, and repair circuitry 215 and/or known as memory I/O training circuitry 115.

The programmable circuitry 1012 of the illustrated example includes a local memory 1013 (e.g., a cache, registers, etc.). The programmable circuitry 1012 of the illustrated example is in communication with main memory 1014, 1016, which includes a volatile memory 1014 and a non-volatile memory 1016, by a bus 1018. The volatile memory 1014 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1016 may be implemented by flash memory and/or any other desired type of memory device. Access to the main memory 1014, 1016 of the illustrated example is controlled by a memory controller 1017. In some examples, the memory controller 1017 may be implemented by one or more integrated circuits, logic circuits, microcontrollers from any desired family or manufacturer, or any other type of circuitry to manage the flow of data going to and from the main memory 1014, 1016.

The programmable circuitry platform 1000 of the illustrated example also includes interface circuitry 1020. The interface circuitry 1020 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1022 are connected to the interface circuitry 1020. The input device(s) 1022 permit(s) a user (e.g., a human user, a machine user, etc.) to enter data and/or commands into the programmable circuitry 1012. The input device(s) 1022 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1024 are also connected to the interface circuitry 1020 of the illustrated example. The output device(s) 1024 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1020 of the illustrated example, thus, typically includes a graphics driver card, a graphics driver chip, and/or graphics processor circuitry such as a GPU.

The interface circuitry 1020 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1000 of the illustrated example also includes one or more mass storage discs or devices 1028 to store firmware, software, and/or data. Examples of such mass storage discs or devices 1028 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1032, which may be implemented by the machine readable instructions of FIG. 8, may be stored in the mass storage device 1028, in the volatile memory 1014, in the non-volatile memory 1016, and/or on at least one non-transitory computer readable storage medium such as a CD or DVD which may be removable.

FIG. 11 is a block diagram of an example implementation of the programmable circuitry 1012 of FIG. 10. In this example, the programmable circuitry 1012 of FIG. 10 is implemented by a microprocessor 1100. For example, the microprocessor 1100 may be a general-purpose microprocessor (e.g., general-purpose microprocessor circuitry). The microprocessor 1100 executes some or all of the machine-readable instructions of the flowchart of FIG. 8 to effectively instantiate the circuitry of FIG. 2 as logic circuits to perform operations corresponding to those machine readable instructions. In some such examples, the circuitry of FIG. 2 is instantiated by the hardware circuits of the microprocessor 1100 in combination with the machine-readable instructions. For example, the microprocessor 1100 may be implemented by multi-core hardware circuitry such as a CPU, a DSP, a GPU, an XPU, etc. Although it may include any number of example cores 1102 (e.g., 1 core), the microprocessor 1100 of this example is a multi-core semiconductor device including N cores. The cores 1102 of the microprocessor 1100 may operate independently or may cooperate to execute machine readable instructions. For example, machine code corresponding to a firmware program, an embedded software program, or a software program may be executed by one of the cores 1102 or may be executed by multiple ones of the cores 1102 at the same or different times. In some examples, the machine code corresponding to the firmware program, the embedded software program, or the software program is split into threads and executed in parallel by two or more of the cores 1102. The software program may correspond to a portion or all of the machine readable instructions and/or operations represented by the flowchart of FIG. 8.

The cores 1102 may communicate by a first example bus 1104. In some examples, the first bus 1104 may be implemented by a communication bus to effectuate communication associated with one(s) of the cores 1102. For example, the first bus 1104 may be implemented by at least one of an Inter-Integrated Circuit (I2C) bus, a Serial Peripheral Interface (SPI) bus, a PCI bus, or a PCIe bus. Additionally or alternatively, the first bus 1104 may be implemented by any other type of computing or electrical bus. The cores 1102 may obtain data, instructions, and/or signals from one or more external devices by example interface circuitry 1106. The cores 1102 may output data, instructions, and/or signals to the one or more external devices by the interface circuitry 1106. Although the cores 1102 of this example include example local memory 1120 (e.g., Level 1 (L1) cache that may be split into an L1 data cache and an L1 instruction cache), the microprocessor 1100 also includes example shared memory 1110 that may be shared by the cores (e.g., Level 2 (L2 cache)) for high-speed access to data and/or instructions. Data and/or instructions may be transferred (e.g., shared) by writing to and/or reading from the shared memory 1110. The local memory 1120 of each of the cores 1102 and the shared memory 1110 may be part of a hierarchy of storage devices including multiple levels of cache memory and the main memory (e.g., the main memory 1014, 1016 of FIG. 10). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1102 may be referred to as a CPU, DSP, GPU, etc., or any other type of hardware circuitry. Each core 1102 includes control unit circuitry 1114, arithmetic and logic (AL) circuitry (sometimes referred to as an ALU) 1116, a plurality of registers 1118, the local memory 1120, and a second example bus 1122. Other structures may be present. For example, each core 1102 may include vector unit circuitry, single instruction multiple data (SIMD) unit circuitry, load/store unit (LSU) circuitry, branch/jump unit circuitry, floating-point unit (FPU) circuitry, etc. The control unit circuitry 1114 includes semiconductor-based circuits structured to control (e.g., coordinate) data movement within the corresponding core 1102. The AL circuitry 1116 includes semiconductor-based circuits structured to perform one or more mathematic and/or logic operations on the data within the corresponding core 1102. The AL circuitry 1116 of some examples performs integer based operations. In other examples, the AL circuitry 1116 also performs floating-point operations. In yet other examples, the AL circuitry 1116 may include first AL circuitry that performs integer-based operations and second AL circuitry that performs floating-point operations. In some examples, the AL circuitry 1116 may be referred to as an Arithmetic Logic Unit (ALU).

The registers 1118 are semiconductor-based structures to store data and/or instructions such as results of one or more of the operations performed by the AL circuitry 1116 of the corresponding core 1102. For example, the registers 1118 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1118 may be arranged in a bank as shown in FIG. 11. Alternatively, the registers 1118 may be organized in any other arrangement, format, or structure, such as by being distributed throughout the core 1102 to shorten access time. The second bus 1122 may be implemented by at least one of an I2C bus, a SPI bus, a PCI bus, or a PCIe bus.

Each core 1102 and/or, more generally, the microprocessor 1100 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1100 is a semiconductor device fabricated to include many transistors interconnected to implement the structures described above in one or more integrated circuits (ICs) contained in one or more packages.

The microprocessor 1100 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1100, in the same chip package as the microprocessor 1100 and/or in one or more separate packages from the microprocessor 1100.

FIG. 12 is a block diagram of another example implementation of the programmable circuitry 1012 of FIG. 10. In this example, the programmable circuitry 1012 is implemented by FPGA circuitry 1200. For example, the FPGA circuitry 1200 may be implemented by an FPGA. The FPGA circuitry 1200 can be used, for example, to perform operations that could otherwise be performed by the example microprocessor 1100 of FIG. 11 executing corresponding machine readable instructions. However, once configured, the FPGA circuitry 1200 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1100 of FIG. 11 described above (which is a general purpose device that may be programmed to execute some or all of the machine readable instructions represented by the flowchart of FIG. 8 but whose interconnections and logic circuitry are fixed once fabricated), the FPGA circuitry 1200 of the example of FIG. 12 includes interconnections and logic circuitry that may be configured, structured, programmed, and/or interconnected in different ways after fabrication to instantiate, for example, some or all of the operations/functions corresponding to the machine readable instructions represented by the flowchart of FIG. 8. In particular, the FPGA circuitry 1200 may be thought of as an array of logic gates, interconnections, and switches. The switches can be programmed to change how the logic gates are interconnected by the interconnections, effectively forming one or more dedicated logic circuits (unless and until the FPGA circuitry 1200 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 8. As such, the FPGA circuitry 1200 may be configured and/or structured to effectively instantiate some or all of the operations/functions corresponding to the machine readable instructions of the flowchart of FIG. 8 as dedicated logic circuits to perform the operations/functions corresponding to those software instructions in a dedicated manner analogous to an ASIC. Therefore, the FPGA circuitry 1200 may perform the operations/functions corresponding to the some or all of the machine readable instructions of FIG. 8 faster than the general-purpose microprocessor can execute the same.

In the example of FIG. 12, the FPGA circuitry 1200 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1200 of FIG. 12 may access and/or load the binary file to cause the FPGA circuitry 1200 of FIG. 12 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1200 of FIG. 12 to cause configuration and/or structuring of the FPGA circuitry 1200 of FIG. 12, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1200 of FIG. 12 may access and/or load the binary file to cause the FPGA circuitry 1200 of FIG. 12 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1200 of FIG. 12 to cause configuration and/or structuring of the FPGA circuitry 1200 of FIG. 12, or portion(s) thereof.

The FPGA circuitry 1200 of FIG. 12, includes example input/output (I/O) circuitry 1202 to obtain and/or output data to/from example configuration circuitry 1204 and/or external hardware 1206. For example, the configuration circuitry 1204 may be implemented by interface circuitry that may obtain a binary file, which may be implemented by a bit stream, data, and/or machine-readable instructions, to configure the FPGA circuitry 1200, or portion(s) thereof. In some such examples, the configuration circuitry 1204 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1206 may be implemented by external hardware circuitry. For example, the external hardware 1206 may be implemented by the microprocessor 1100 of FIG. 11.

The FPGA circuitry 1200 also includes an array of example logic gate circuitry 1208, a plurality of example configurable interconnections 1210, and example storage circuitry 1212. The logic gate circuitry 1208 and the configurable interconnections 1210 are configurable to instantiate one or more operations/functions that may correspond to at least some of the machine readable instructions of FIG. 8 and/or other desired operations. The logic gate circuitry 1208 shown in FIG. 12 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1208 to enable configuration of the electrical structures and/or the logic gates to form circuits to perform desired operations/functions. The logic gate circuitry 1208 may include other electrical structures such as look-up tables (LUTs), registers (e.g., flip-flops or latches), multiplexers, etc.

The configurable interconnections 1210 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1208 to program desired logic circuits.

The storage circuitry 1212 of the illustrated example is structured to store result(s) of the one or more of the operations performed by corresponding logic gates. The storage circuitry 1212 may be implemented by registers or the like. In the illustrated example, the storage circuitry 1212 is distributed amongst the logic gate circuitry 1208 to facilitate access and increase execution speed.

The example FPGA circuitry 1200 of FIG. 12 also includes example dedicated operations circuitry 1214. In this example, the dedicated operations circuitry 1214 includes special purpose circuitry 1216 that may be invoked to implement commonly used functions to avoid the need to program those functions in the field. Examples of such special purpose circuitry 1216 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1200 may also include example general purpose programmable circuitry 1218 such as an example CPU 1220 and/or an example DSP 1222. Other general purpose programmable circuitry 1218 may additionally or alternatively be present such as a GPU, an XPU, etc., that can be programmed to perform other operations.

Although FIGS. 11 and 12 illustrate two example implementations of the programmable circuitry 1012 of FIG. 10, many other approaches are contemplated. For example, FPGA circuitry may include an on-board CPU, such as one or more of the example CPU 1220 of FIG. 11. Therefore, the programmable circuitry 1012 of FIG. 10 may additionally be implemented by combining at least the example microprocessor 1100 of FIG. 11 and the example FPGA circuitry 1200 of FIG. 12. In some such hybrid examples, one or more cores 1102 of FIG. 11 may execute a first portion of the machine readable instructions represented by the flowchart(s) of FIG. 8 to perform first operation(s)/function(s), the FPGA circuitry 1200 of FIG. 12 may be configured and/or structured to perform second operation(s)/function(s) corresponding to a second portion of the machine readable instructions represented by the flowchart of FIG. 8, and/or an ASIC may be configured and/or structured to perform third operation(s)/function(s) corresponding to a third portion of the machine readable instructions represented by the flowchart of FIG. 8.

It should be understood that some or all of the circuitry of FIG. 2 may, thus, be instantiated at the same or different times. For example, same and/or different portion(s) of the microprocessor 1100 of FIG. 11 may be programmed to execute portion(s) of machine-readable instructions at the same and/or different times. In some examples, same and/or different portion(s) of the FPGA circuitry 1200 of FIG. 12 may be configured and/or structured to perform operations/functions corresponding to portion(s) of machine-readable instructions at the same and/or different times.

In some examples, some or all of the circuitry of FIG. 2 may be instantiated, for example, in one or more threads executing concurrently and/or in series. For example, the microprocessor 1100 of FIG. 11 may execute machine readable instructions in one or more threads executing concurrently and/or in series. In some examples, the FPGA circuitry 1200 of FIG. 12 may be configured and/or structured to carry out operations/functions concurrently and/or in series. Moreover, in some examples, some or all of the circuitry of FIG. 2 may be implemented within one or more virtual machines and/or containers executing on the microprocessor 1100 of FIG. 11.

In some examples, the programmable circuitry 1012 of FIG. 10 may be in one or more packages. For example, the microprocessor 1100 of FIG. 11 and/or the FPGA circuitry 1200 of FIG. 12 may be in one or more packages. In some examples, an XPU may be implemented by the programmable circuitry 1012 of FIG. 10, which may be in one or more packages. For example, the XPU may include a CPU (e.g., the microprocessor 1100 of FIG. 11, the CPU 1220 of FIG. 12, etc.) in one package, a DSP (e.g., the DSP 1222 of FIG. 12) in another package, a GPU in yet another package, and an FPGA (e.g., the FPGA circuitry 1200 of FIG. 12) in still yet another package.

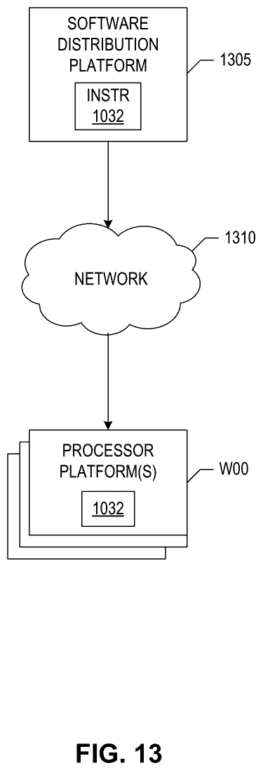

A block diagram illustrating an example software distribution platform 1305 to distribute software such as the example machine readable instructions 1032 of FIG. 10 to other hardware devices (e.g., hardware devices owned and/or operated by third parties from the owner and/or operator of the software distribution platform) is illustrated in FIG. 13. The example software distribution platform 1305 may be implemented by any computer server, data facility, cloud service, etc., capable of storing and transmitting software to other computing devices. The third parties may be customers of the entity owning and/or operating the software distribution platform 1305. For example, the entity that owns and/or operates the software distribution platform 1305 may be a developer, a seller, and/or a licensor of software such as the example machine readable instructions 1032 of FIG. 10. The third parties may be consumers, users, retailers, OEMs, etc., who purchase and/or license the software for use and/or re-sale and/or sub-licensing. In the illustrated example, the software distribution platform 1305 includes one or more servers and one or more storage devices. The storage devices store the machine readable instructions 1032, which may correspond to the example machine readable instructions of FIG. 8, as described above. The one or more servers of the example software distribution platform 1305 are in communication with an example network 1310, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1032 from the software distribution platform 1305. For example, the software, which may correspond to the example machine readable instructions of FIG. 8, may be downloaded to the example programmable circuitry platform 1000, which is to execute the machine readable instructions 1032 to implement the memory I/O training circuitry 115. In some examples, one or more servers of the software distribution platform 1305 periodically offer, transmit, and/or force updates to the software (e.g., the example machine readable instructions 1032 of FIG. 10) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that relates generally to dynamic random access memory initialization and, more particularly, to method and apparatus to improve memory reliability by dynamically selecting memory address for write DQ delay training.

Disclosed systems, apparatus, articles of manufacture, and methods improve the efficiency of using a computing device by improving memory reliability by dynamically selecting memory address for write DQ delay training. Disclosed systems, apparatus, articles of manufacture, and methods are accordingly directed to one or more improvement(s) in the operation of a machine such as a computer or other electronic and/or mechanical device.

It is noted that this patent arises from a continuation in part of International Application No. PCT/CN2024/080233 and claims priority from the International Application No. PCT/CN2024/080233, which was filed on Mar. 6, 2024, and is hereby incorporated by reference in its entirety.

Example methods, apparatus, systems, and articles of manufacture to improve memory reliability by dynamically selecting memory address for write DQ delay training are disclosed herein. Further examples and combinations thereof include the following:
Example 1 includes a non-transitory computer readable medium comprising instructions that, when executed, cause a machine to determine a first memory address at which to perform memory input/output training based on an identification of a second memory address that is associated with an error, and cause the memory input/output training to be performed at the first memory address.
Example 2 includes the non-transitory computer readable medium of example 1, wherein the memory address identifies a row.
Example 3 includes the non-transitory computer readable medium of example 1, wherein the instructions, when executed, cause the machine to determine the first memory address based on the first memory address identifying a row that does not include any memory addresses associated with an error.
Example 4 includes the non-transitory computer readable medium of example 1, wherein the instructions, when executed, cause the machine to determine the first memory address based on the first memory address identifying a row that does not include any memory addresses associated with an error across multiple memory modules example 5 includes the non-transitory computer readable medium of example 1, wherein the second memory address is identified in a list of memory addresses associated with errors.
Example 6 includes the non-transitory computer readable medium of example 5, wherein the list is a post package repair (PPR) list.
Example 7 includes the non-transitory computer readable medium of example 1, wherein the memory input/output training is write data queue delay training.
Example 8 includes the non-transitory computer readable medium of example 1, wherein the instructions are basic input output system instructions.
Example 9 includes the non-transitory computer readable medium of example 1, wherein the non-transitory computer readable medium is flash memory coupled to a motherboard.
Example 10 includes the non-transitory computer readable medium of example 1, wherein the instructions, when executed, cause the machine to select a third memory address for the memory input/output training if the memory input/output training with the first memory address fails.
Example 11 includes the non-transitory computer readable medium of example 1, wherein the instructions, when executed, cause the machine to select a third memory address for the memory input/output training if the memory input/output training detects a zero margin.
Example 12 includes an apparatus comprising interface circuitry, machine-readable instructions, and at least one processor circuit programmed by the machine-readable instructions to perform memory input/output training using a first memory address, determine that a result of the memory input/output training is an error, and retry the memory input/output training using a second memory address.
Example 13 includes the apparatus of example 12, wherein to perform the memory input/output training, the at least one processor is to write data to physical memory at a first memory address at a first time, and read data stored at the first memory address at a second time later than the first time.
Example 14 includes the apparatus of example 13, wherein to perform the memory input/output training, the at least one processor is to determine the error when the read data does not match the written data.
Example 15 includes the apparatus of example 12, wherein the at least one processor is to cause a repair operation to be performed for the first memory address after the error is determined.
Example 16 includes a method comprising performing a read/write training test on first memory addresses, performing, by at least one processor circuit programmed by at least one instruction, the read/write training test on second memory addresses in response to a failed test using first memory addresses, and repairing, by one or more of the at least one processor circuit, the first memory addresses.
Example 17 includes the method of example 16, further comprising selecting the first memory addresses based on a list of memory addresses for which errors have been previously detected.
Example 18 includes the method of example 17, wherein selecting the first memory address includes determining a row of a plurality of memory modules, wherein the row does not include a memory address with an error on the list for any of the modules.
Example 19 includes the method of example 16, wherein performing the read/write training test on the first memory addresses includes writing data to physical memory at a first memory address of the first memory addresses at a first time, and reading data stored at the first memory address at a second time later than the first time.
Example 20 includes the method of example 19, further including determining that the read/write training test failed when the read data does not match the written data.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A non-transitory computer readable medium comprising instructions that, when executed, cause a machine to:
determine a first memory address at which to perform memory input/output training based on an identification of a second memory address that is associated with an error; and
cause the memory input/output training to be performed at the first memory address.

2. The non-transitory computer readable medium of claim 1, wherein the memory address identifies a row.

3. The non-transitory computer readable medium of claim 1, wherein the instructions, when executed, cause the machine to determine the first memory address based on the first memory address identifying a row that does not include any memory addresses associated with an error.

4. The non-transitory computer readable medium of claim 1, wherein the instructions, when executed, cause the machine to determine the first memory address based on the first memory address identifying a row that does not include any memory addresses associated with an error across multiple memory modules.

5. The non-transitory computer readable medium of claim 1, wherein the second memory address is identified in a list of memory addresses associated with errors.

6. The non-transitory computer readable medium of claim 5, wherein the list is a post package repair (PPR) list.

7. The non-transitory computer readable medium of claim 1, wherein the memory input/output training is write data queue delay training.

8. The non-transitory computer readable medium of claim 1, wherein the instructions are basic input output system instructions.

9. The non-transitory computer readable medium of claim 1, wherein the non-transitory computer readable medium is flash memory coupled to a motherboard.

10. The non-transitory computer readable medium of claim 1, wherein the instructions, when executed, cause the machine to select a third memory address for the memory input/output training if the memory input/output training with the first memory address fails.

11. The non-transitory computer readable medium of claim 1, wherein the instructions, when executed, cause the machine to select a third memory address for the memory input/output training if the memory input/output training detects a zero margin.

12. An apparatus comprising:
interface circuitry;
machine-readable instructions; and
at least one processor circuit programmed by the machine-readable instructions to:
perform memory input/output training using a first memory address;
determine that a result of the memory input/output training is an error; and
retry the memory input/output training using a second memory address.

13. The apparatus of claim 12, wherein to perform the memory input/output training, the at least one processor is to:
write data to physical memory at a first memory address at a first time; and
read data stored at the first memory address at a second time later than the first time.

14. The apparatus of claim 13, wherein to perform the memory input/output training, the at least one processor is to determine the error when the read data does not match the written data.

15. The apparatus of claim 12, wherein the at least one processor is to cause a repair operation to be performed for the first memory address after the error is determined.

16. A method comprising:
performing a read/write training test on first memory addresses;
performing, by at least one processor circuit programmed by at least one instruction, the read/write training test on second memory addresses in response to a failed test using first memory addresses; and
repairing, by one or more of the at least one processor circuit, the first memory addresses.

17. The method of claim 16, further comprising selecting the first memory addresses based on a list of memory addresses for which errors have been previously detected.

18. The method of claim 17, wherein selecting the first memory address includes determining a row of a plurality of memory modules, wherein the row does not include a memory address with an error on the list for any of the modules.

19. The method of claim 16, wherein performing the read/write training test on the first memory addresses includes:
writing data to physical memory at a first memory address of the first memory addresses at a first time; and
reading data stored at the first memory address at a second time later than the first time.

20. The method of claim 19, further including determining that the read/write training test failed when the read data does not match the written data.
